(19) United States
(12) Patent Application Publication
(10) Pub. No.: US 2015/0177333 A1
(43) Pub. Date: Jun. 25, 2015

(54) METHOD FOR MANAGING AND DIAGNOSING A BATTERY

(71) Applicant: COMMISSARIAT A L'ENERGIE ATOMIQUE ET AUX ENERGIES ALTERNATIVES, Paris (FR)

(72) Inventor: Maxime Montaru, Chambery (FR)

(73) Assignee: COMMISSARIAT A L'ENERGIE ATOMIQUE ET AUX ENERGIES ALTERNATIVES, Paris (FR)

(21) Appl. No.: 14/419,731

(22) PCT Filed: Aug. 6, 2013
(86) PCT No.: PCT/EP2013/066434

§ 371 Date: Feb. 5, 2015

(30) Foreign Application Priority Data
Aug. 6, 2012 (FR) 12 57633

(51) Int. Cl. G01R 31/36

(52) U.S. Cl. CPC G01R 31/3679; G01R 31/3627

(57) ABSTRACT

A method for managing a battery, characterized in that it includes the following steps:
discharging the battery to a full discharge level (E1) and measuring the temperature Tfindch of the battery (E2) when the full discharge level is reached; and
charging the battery to a full charge level (E3) and measuring the temperature Tfinch of the battery (E4) when the full charge level is reached,
   these two steps of charging then discharging or charging then discharging being consecutive.

The invention relates to a method for managing a battery, including notably the performance of the battery diagnostics, the indication of the state of charge and the state of health of the battery, in order to control the change in its state over time, i.e. its aging. It also relates to a battery as such, including an arrangement to carry out this management method. Finally, it also relates to a battery management system carrying out this battery management method.

The knowledge of the state of a battery includes notably the calculation of its state of charge at any time during its existence, which is indispensable for being able to use it in an optimum manner. This calculation of the state of charge requires a knowledge of the reference capacity of the battery, referred to as Cref. This reference capacity represents the maximum charge quantity which the initially charged battery can release during a discharge; the charging and discharging are carried out under nominal conditions (current states or profile, temperature, end-of-charge and end-of-discharge criteria). This reference capacity reduces over time, since the performance of the battery decreases as it ages. It is therefore customary to perform regularly a full discharge of the battery then a full charge, during which the charge quantity released and stored by the battery is measured, in order to determine from it the new value of the reference capacity at the chosen time. These battery measurement and diagnosis phases generally occur in a chosen and known environment, notably at a constant temperature and in an imposed current state, i.e. a state close to nominal conditions. These solutions are therefore unsuitable for managing on-board batteries for which the operation must be reliable and known in an uncontrolled and highly variable environment.

In order to refine this method of estimating the state of charge of a battery, document US2007/0236183 proposes a solution which takes account notably of the reduction in the reference capacity of a battery over time, and of its temperature dependence, this dependence being assumed to be known. This document thus determines a value of the state of charge of a battery on the basis of a phase of full charging or discharging of the battery, by applying a slight correction compared with the previously described method. However, the result obtained remains inadequate.

A general object of the invention is therefore to propose a solution for managing a battery which improves its diagnosis, notably the knowledge of its state, despite an uncontrolled environment, in order to derive therefrom a precise estimation at any time and at any age of its state of charge.

For this purpose, the invention is based on a method for managing a battery, characterized in that it comprises the following steps:
discharging the battery to a full discharge level and measuring the temperature Tfindch of the battery when the full discharge level is reached; and
charging the battery to a full charge level and measuring the temperature Tfinch of the battery when the full charge level is reached, these two steps of charging then discharging or charging then discharging being consecutive; and
calculating the inaccessible charge quantity Qdch(Tfindch) at the end-of-discharge temperature Tfindch following the step of discharging to a level of full discharge of the battery, knowing the relation giving the inaccessible charge quantity Qdch(T) of the battery as a function of the temperature T, and
calculating the maximum admissible charge quantity Qch(Tfinch) of the battery at the end-of-charge temperature Tfinch, by the relation Qch(Tfinch)=qch+Qdch(Tfindch), where qch corresponds to the quantity of charges transmitted to or released by the battery to change from a full discharge level to a full charge level or vice versa.

The invention is defined more precisely by the claims.

These objects, characteristics and advantages of the present invention will be explained in detail in the following description of a particular embodiment, given in a non-limiting manner in relation to the attached figures, in which:

FIG. 1 shows respectively the change in the admissible charge quantity and the inaccessible charge quantity, as a function of temperature, for a given battery when it is fully charged or fully discharged.

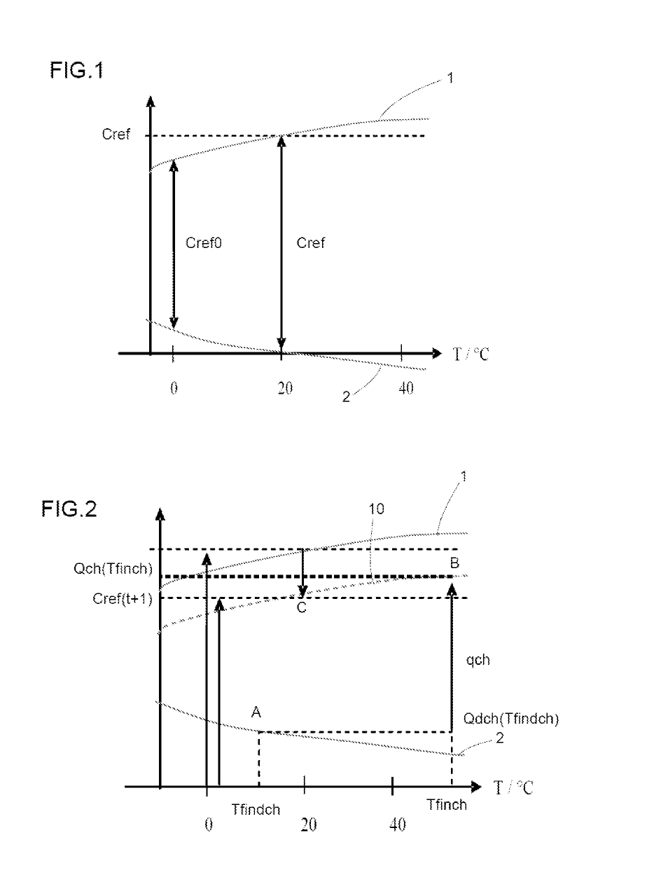

FIG. 2 shows the performance of steps of the method for managing a battery according to one embodiment of the invention.

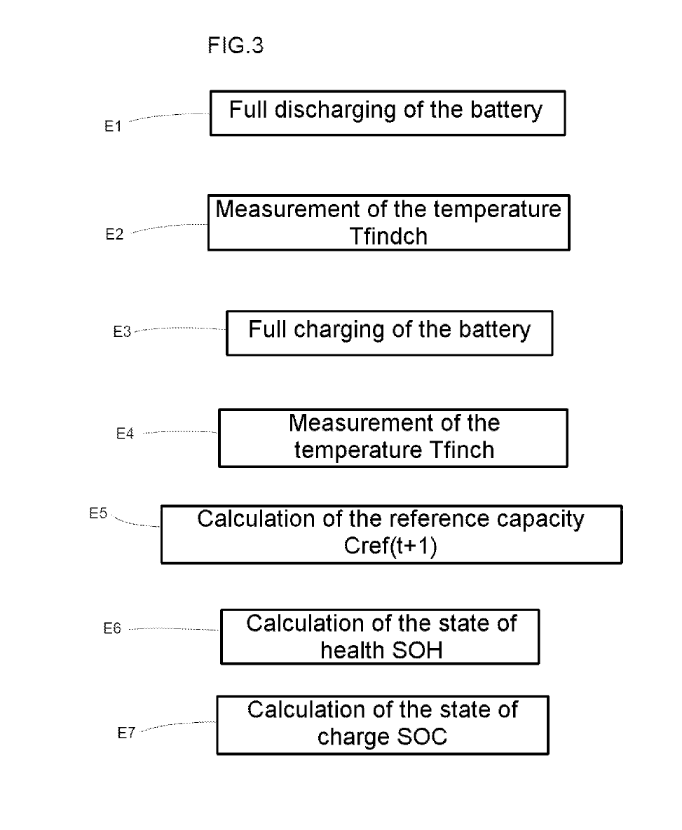

FIG. 3 shows a flow diagram of a battery management method according to one embodiment of the invention.

The curve 1 in FIG. 1 shows the change in the admissible charge quantity of a battery as a function of temperature. It therefore shows that, for the same battery, fully discharged in advance under nominal conditions, when it is charged under the same charging conditions, i.e. with the same electrical current and voltage conditions, for different temperatures, the higher the temperature is raised, the more the released final charge quantity is increased. Conventionally, the reference capacity Cref, previously defined and normally taken into account, is the capacity obtained on this curve 1 for a reference temperature Tref, for example of 20° C. It should be noted that the curve 1 is defined for a certain current level or profile corresponding to the measured (or associated) recharge current at the time of detection of the end-of-charge criterion. The curve 1 can thus be regarded as a surface if a plurality of charging states are taken into account.

The curve 2 in FIG. 1 shows the change in the inaccessible charge quantity on discharge of a battery as a function of temperature, i.e. the charge quantity which remains stored in the battery after its full discharge according to the end-of-discharge criterion and which is not usable for the power supply of a device. The same discharge and end-of-discharge criterion conditions are applied, regardless of the temperature of the element during the discharge. Nevertheless, according to the application, it is conceivable to have conditions and end-of-discharge criteria that are variable according to temperature. By choice of graphical representation, this inaccessible charge quantity is positioned on the axis of origin for the reference temperature of 20° C. It appears that the more the temperature increases, the more this inaccessible charge quantity decreases. It should be noted, as stated with reference to the curve 1, that the curve 2 is defined for a certain current level corresponding to the measured (or associated) discharge current at the time of detection of the end-of-charge criterion. The curve 2 can therefore be regarded as a surface if a plurality of discharge conditions are taken into account.

Thus, the reference capacity Cref of a battery is released when the battery is fully charged at 20° C., then discharged at this same temperature. If the temperature changes, the available and releasable charge will finally be different, such as Cref0, for example, at 0° C.

The two curves 1, 2 described above may be known when the battery is in a new condition, may be provided by the battery manufacturer, or may be determined empirically by testing the battery for different temperatures and different electrical (current or power) load states. Notably, the initial reference capacity Crefo of the battery in the new condition is therefore known. These two curves 1, 2 can obviously be replaced with charts providing a number of charge quantity values as a function of temperature, i.e. a number of points on the curves 1, 2, the others being obtained by means of an extrapolation, or by means of any other equivalent presentation of this knowledge.

These curves 1, 2 are defined for specific experimental conditions which can be characterized by three criteria. The first criterion corresponds to the electrical load profile applied to the battery terminals, which may be a constant or dynamic current, voltage or power control involving one or more steps. This profile is applied until the end-of-charge or end-of-discharge criterion is met. The second criterion corresponds to the end-of-charge or end-of-discharge criterion. It corresponds either to the exceeding of a threshold by one or more measured or estimated variables, such as the current, voltage, power or temperature, or to the exceeding of a threshold by variables within the management system, such as the current or the authorized power, the activation of a specific operating mode (degraded mode, end-of-balancing, etc.). The third criterion corresponds to the variables used to reference the measured charge quantity in the diagram. The temperature, which defines the positioning on the x-axis, may be a raw or filtered, measured or estimated temperature in a battery or battery pack. Moreover, the measurement point is characteristic either of the average current (or power) state during the discharging or charging, or the current (or power) state measured when the end-of-discharge or end-of-charge criterion is detected. By way of example, the curves in FIG. 2 are provided for discharge Pfindch and charge Pfinch powers reached at the time of detection of the end-of-discharge and end-of-charge criterion respectively.

One embodiment of the invention is therefore based on a management method which estimates a state of a battery by considering the temperature in both a charging and a successive discharging phase in order to take account of the phenomena shown by the curves 1, 2 in FIG. 1.

FIG. 2 therefore shows a battery management method according to a first embodiment of the invention. The curve 1 remains the curve explained in FIG. 1 for a time t. In this embodiment of the invention, the performance of the battery is assumed to decrease over time, which is evident in the form of a simple vertical translation movement down this curve 1, which thus descends towards a curve 10 at an assumed subsequent time t+1. According to this hypothesis, the curve 10 therefore remains parallel to the curve 1, thus enabling it to be retraced entirely once a single point of this curve has been defined. The maximum admissible charge quantity Qch(T) as a function of the temperature T can thus be written as F(T)+K, where K is a constant varying as a function of the ageing of the battery (and could thus, for example, be written as a function of the state of health SOH of the battery, K(SOH)), and where F(T) is a function more or less invariant with the ageing of the battery which may, for example, conventionally correspond to the curve Qch(T) when the battery is in the new condition, in which case K=0 when the battery is new.

Similarly, the curve 2 remains the curve described in FIG. 1. In this embodiment of the invention, this curve is assumed to remain invariable over time.

The battery management method thus includes a first phase including the calculation of the reference capacity Cref(t+1) at an assumed time t+1.

For this purpose, a first step E1 includes the full discharging of the battery. The end-of-discharge criterion is the customary criterion, given by the manufacturer. Any end-of-discharge criterion can be applied, corresponding to a situation in which the battery releases no more or almost no more energy, in the system into which it is integrated. In this first embodiment, this discharging is effected under nominal electrical conditions. All the discharges implemented take place under the same conditions or under similar conditions, provided that they meet certain similarity criteria (average state, load peak characteristics, ration of non-utilization time to utilization time). It should be noted that this discharging is implemented starting from any given initial state of the battery.

A second step E2 then includes the recording of the end-of-discharge temperature Tfindch, and, optionally, the discharge current state Ifindch reached when the end-of-discharge criterion is detected, as will be explained below in connection with a second embodiment. The residual charge quantity Qdch(Tfindch) is obtained at the point A on the curve 2 as a function of this temperature.

A third step E3 then consists in a full recharging of the battery. This recharging is also effected, for example, under the nominal electrical conditions defined by the battery manufacturer, the end-of-charge criterion also being the criterion defined by the manufacturer. Any battery-charging method can obviously be used, with any associated end-of-charge criterion. According to this embodiment, all the charging operations implemented during this management method are performed under the same electrical conditions or under similar conditions, provided that they meet certain similarity criteria (average state, load peak characteristics, ratio of non-utilization time to utilization time). During this charging, the charge qch transmitted to the battery is measured. This charge is, for example, obtained by the following formula, integrated over the duration of the charging phase: qch=∫I dt, where I is the charging current. This current can be measured by a sensor, or alternatively, it can be estimated by any model or any other method.

A fourth step E4 of measuring the end-of-charge temperature Tfinch identifies the end-of-charge point B which corresponds to the charge quantity Qch(Tfinch) on the curve 10, since this value is calculated by: Qch(Tfinch)=qch+Qdch(Tfindch). This point B belongs to the curve 10 and, as previously seen, the knowledge of a single point enables the entire curve 10 to be traced. Notably, a function Qref can be introduced to calculate the reference capacity on the basis of an admissible charge quantity Qch(T) at any given temperature T. This function Qref remains the same over time since the curve 1 undergoes a translation movement, as previously explained, and it can be defined in an initial phase once the curve 1 in the new condition of the battery is known. Thus, the following relation applies at any time: Cref=Qref (Qch(T),T). It should be noted that this measurement of the end-of-charge temperature Tfinch is advantageously carried out when the end-of-charge criterion is met.

A fifth step E5 then includes the calculation of the reference capacity Cref(t+1) of the battery at the time t+1, assuming that the point C on this curve 10 is at the reference temperature. This determination can be presented using the previously described function Qref, by the relation Cref(t+1)=Qref(Qch(Tfinch),Tfinch). Alternatively, this same reality can be denoted according to the following approach, as previously explained:

Cref(t)=F(Tref)+K(SOH(t))et Cref(t+1)=F(Tref)+K(SOH(t+1))

The knowledge of the end-of-charge charge point B allows the function K(SOH(t+1)) to be known.

It is then evident that, at each time t, Cref(t)=Qch(Tref)−Qdch(Tref). It should be noted that, in the chosen example in FIG. 1, the function Qdch has been normalized in such a way that Qdch(Tref)=0: in such an example, for any ageing of the battery, the preceding relation becomes Cref=Qch(Tref).

A variant of the method described above can obviously be obtained by reversing the full charging then discharging steps. It is important to carry out these two steps consecutively. In this alternative, the first step then consists in a full charging of the battery, until the end-of-charge criterion is met, starting from its any given initial state. The second step then consists in measuring the temperature Tfinch. The third step consists in a full discharging of the battery, until the discharge criterion is met. During this full discharging, the charge quantity qch released by the battery is measured or estimated. In a fourth step, the end-of-discharge temperature Tfindch is measured. These steps similarly define the point B on the curve 10, since it is possible to calculate Qch(Tfinch)=Qdch(Tfindch)+qch. This alternative method is therefore very similar to the method described in more detail above.

The temperature measurement and current and/or voltage measurement steps during the charging and discharging steps can be replaced by estimations of all or some of these quantities by a calculation model.

When the reference capacity is precisely known at a time t+1, despite the discharging and charging conditions at temperatures which may be any given, different, temperatures, the battery management method then includes a second phase which consists in determining the state of the battery with precision.

A step of calculating its state of health (SOH) E6 can thus be implemented, for example, by determining the ratio between the obtained reference capacity Cref(t+1) and the initial reference capacity Crefo when the battery is in the new condition.

SOH=Cref(t+1)/Crefo

Furthermore, a step of calculating its state of charge (SOC) E7 can also be implemented, by means of the following ratio:

SOC=(Qch(Tfinch)−qdch−Qdch(Tf))/(Qch(Tfinch)−Qdch(T))

### Where

qdch is the charge quantity released by the battery since its last full charging, this quantity corresponding to a cumulation of the charge quantities released and transmitted during partial charging and discharging phases since the last full charging,
Qdch(Tf) is the non-releasable charge quantity, at the estimated end-of-discharge temperature Tf of the battery. The temperature Tf may be parameterizable online or offline according to the application,
Qch(Tfinch) is the maximum admissible charge received by the battery during the last charging.
It should be noted that this definition of the state of charge SOC of the battery takes account of its temperature T at the time concerned, which may be chosen as an estimation of the end-of-discharge temperature Tf in the above calculation, and also its temperature during its preceding charging.

The second battery management phase can also allow predictions to be made. In fact, the charge releasable by the battery for a certain operating temperature can be anticipated at any time.

As previously explained, the first embodiment implements steps of discharging and charging the battery under controlled and always identical electrical conditions. A second embodiment of the invention may include all the preceding steps, but by taking account of the charging and discharging current of the battery, in addition to the temperature. Thus, all of the preceding calculations are modified in order to integrate two variable parameters, the temperature and current, and curves similar to curves 1, 2 in FIG. 1 are modified on the surface, having an additional dimension, used to characterize the variation in the charge quantities as a function of the temperature and current. The battery management method can thus be suitable for an environment in which any given temperature and current conditions prevail. This second embodiment is simply obtained by adding the current variable I in all the preceding equations in which a temperature dependence is specified.

This battery management method is suitable for any battery, and is particularly useful for the management of batteries which are disposed in an uncontrollable thermal environment and for which a full discharging and charging is possible. It is therefore well suited to an electric vehicle, such as a bicycle, car, bus, lorry, etc. More generally, it is also suitable for any applications for which the thermal conditions are variable (stationary and/or mobile applications). Moreover, it is compatible with any battery technology, particularly that involving a faradaic efficiency which is unitary or close to 1, such as lithium batteries, for example LiFePO4/graphite batteries. An extension is possible for aqueous batteries (lead, NiMH) by integrating a faradaic efficiency mapping as a function of the current and temperature.

The invention also relates to a battery associated with a management system, which includes hardware and/or software means and at least one computer in order to carry out the battery management method described above. This management system notably controls the battery charging and discharging phases, the steps of calculating, measuring and/or estimating variables such as the temperature, current, voltage, etc. This battery management system is or is not integrated within the battery structure. The battery advantageously includes at least one temperature sensor to measure its temperature and transmit it to the computer. The management system furthermore includes a memory to store all of the values measured and/or calculated in the different steps of the method.

1. A method for managing a battery, comprising:
discharging the battery to a full discharge level (E1) and measuring the temperature Tfindch of the battery (E2) when the full discharge level is reached; and
charging the battery to a full charge level (E3) and measuring the temperature Tfinch of the battery (E4) when the full charge level is reached,
these two steps of charging then discharging or charging then discharging being consecutive; and
calculating the inaccessible charge quantity Qdch(Tfindch) at the end-of-discharge temperature Tfindch following the step of discharging to a level of full discharge of the battery, knowing the relation giving the inaccessible charge quantity Qdch(T) of the battery as a function of the temperature T, and
calculating the maximum admissible charge quantity Qch(Tfinch) of the battery at the end-of-charge temperature Tfinch, by the relation Qch(Tfinch)=qch+Qdch(Tfindch), where qch corresponds to the quantity of charges transmitted to or released by the battery to change from a full discharge level to a full charge level or vice versa.

2. Method for managing a battery according to claim 1, wherein the curve showing the change in the maximum admissible charge quantity Qch(T) as a function of the temperature T undergoes a downward vertical translation movement with the ageing of the battery, Qch(T) being equal to F(T)+K, where K is a constant varying as a function of the ageing of the battery and F(T) is a predefined function more or less invariant with the ageing of the battery.

3. Method for managing a battery according to claim 1, comprising the following steps at a time t:
discharging the battery to a full discharge level (E1),
measuring or estimating the end-of-discharge temperature Tfindch (E2),
charging the battery to a full charge level and measuring or estimating the charge quantity qch transmitted to the battery (E3),
measuring or estimating the temperature Tfinch at the end of full charging (E4),
determining the maximum admissible charge quantity Qch(Tfinch) of the battery at the end-of-charge temperature Tfinch, by the relation Qch(Tfinch)=qch+Qdch(Tfindch),
OR
charging the battery to a full charge level (E1),
measuring or estimating the end-of-charge temperature Tfinch (E2),
discharging the battery to a full discharge level and measuring or estimating the charge quantity qch released by the battery (E3),
measuring or estimating the temperature Tfindch at the end of full discharging (E4),
determining the maximum admissible charge quantity Qch(Tfinch) of the battery at the end-of-charge temperature Tfinch, by the relation Qch(Tfinch)=qch+Qdch(Tfindch), where Qdch(Tfindch) is the inaccessible charge quantity of the battery at the end-of-discharge temperature Tfindch.

4. Method for managing a battery according to claim 2, comprising estimating, at a given time t, the value of a reference capacity Cref(t) of the battery at a reference temperature Tref, Cref corresponding to the maximum admissible charge quantity Qch(Tref) at the reference temperature, minus the inaccessible charge quantity Qdch(Tref) at the reference temperature, the relation Qch(T) concerned being such that Qch(Tfinch) is equal to the previously calculated value qch+Qdch(Tfindch).

5. Method for managing a battery according to claim 3, additionally comprising determining (E5) the reference capacity Cref(t) from the maximum admissible charge Qch(Tfinch), by means of a function Qref in the following manner: Cref(t)=Qref (Qch(Tfinch), Tfinch).

6. Method for managing a battery according to claim 3, wherein the measurement or estimation of the charge quantity qch transmitted to or released by the battery during its charging/discharging is obtained by means of the following formula, integrated over the duration of the battery charging/discharging phase: qch=∫I dt, where I is the charging/discharging current.

7. Method for managing a battery according to claim 1, comprising assuming that the change in the inaccessible charge quantity Qdch(T) of the battery as a function of the temperature T remains constant with the ageing of the battery.

8. Method for managing a battery according to claim 1, comprising calculating the state of health SOH (E6) of the battery at a time t by means of the formula SOH=Cref(t)/Crefo, where Crefo represents the reference capacity of the new battery.

9. Method for managing a battery according to claim 1, comprising calculating its state of charge SOC (E7) by means of the following formula:
SOC=(Qch(Tfinch)−qdch−Qdch(Tf))/(Qch(Tfinch)−Qdch(T))
Where
qdch is the charge quantity released by the battery since its last full charging,
Qdch(Tf) is the non-releasable charge quantity, at the estimated end-of-discharge temperature Tf of the battery, which may be parameterizable online or offline according to the application,
Qch(Tfinch) is the maximum admissible charge received by the battery during its last charging.

10. Method for managing a battery according claim 1, comprising taking account of the current in order to determine the admissible charge quantities at the end of charging and the inaccessible charge quantities at the end of discharging.

11. Battery comprising a computer which carries out the battery management method according to claim 1.

12. Battery management system comprising at least one computer which carries out the battery management method according to claim 1.

13. Computer medium readable by a management unit comprising a recorded computer program including computer program code means for carrying out the battery management method according to claim 1.

14. Method for managing a battery according to claim 2, comprising the following steps at a time t:
discharging the battery to a full discharge level (E1),
measuring or estimating the end-of-discharge temperature Tfindch (E2),
charging the battery to a full charge level and measuring or estimating the charge quantity qch transmitted to the battery (E3),
measuring or estimating the temperature Tfinch at the end of full charging (E4),
determining the maximum admissible charge quantity Qch(Tfinch) of the battery at the end-of-charge temperature Tfinch, by the relation Qch(Tfinch)=qch'Qdch(Tfindch),
OR
charging the battery to a full charge level (E1),
measuring or estimating the end-of-charge temperature Tfinch (E2),
discharging the battery to a full discharge level and measuring or estimating the charge quantity qch released by the battery (E3),
measuring or estimating the temperature Tfindch at the end of full discharging (E4),
determining the maximum admissible charge quantity Qch(Tfinch) of the battery at the end-of-charge temperature Tfinch, by the relation Qch(Tfinch)=qch+Qdch(Tfindch), where Qdch(Tfindch) is the inaccessible charge quantity of the battery at the end-of-discharge temperature Tfindch.

15. Method for managing a battery according to claim 14, additionally comprising determining (E5) the reference capacity Cref(t) from the maximum admissible charge Qch(Tfinch), by means of a function Qref in the following manner: Cref(t)=Qref(Qch(Tfinch), Tfinch).

16. Method for managing a battery according to claim 14, wherein the measurement or estimation of the charge quantity qch transmitted to or released by the battery during its charging/discharging is obtained by means of the following formula, integrated over the duration of the battery charging/discharging phase: qch=∫I dt, where I is the charging/discharging current.

17. Method for managing a battery according to claim 4, additionally comprising determining (E5) the reference capacity Cref(t) from the maximum admissible charge Qch(Tfinch), by means of a function Qref in the following manner: Cref(t)=Qref (Qch(Tfinch), Tfinch).

18. Method for managing a battery according to claim 4, wherein the measurement or estimation of the charge quantity qch transmitted to or released by the battery during its charging/discharging is obtained by means of the following formula, integrated over the duration of the battery charging/discharging phase: qch=∫I dt, where I is the charging/discharging current.

19. Method for managing a battery according to claim 2, comprising assuming that the change in the inaccessible charge quantity Qdch(T) of the battery as a function of the temperature T remains constant with the ageing of the battery.

20. Method for managing a battery according to claim 3, comprising assuming that the change in the inaccessible charge quantity Qdch(T) of the battery as a function of the temperature T remains constant with the ageing of the battery.
